(19) United States
(12) Patent Application Publication
(10) Pub. No.: US 2005/0068080 A1
(43) Pub. Date: Mar. 31, 2005

(54) Timing-flexible flip-flop element

(76) Inventor: Yew-San Lee, Hsin-Chu (TW)

Correspondence Address: BIRCH STEWART KOLASCH & BIRCH, PO BOX 747, FALLS CHURCH, VA, 22040-0747, US

(21) Appl. No.: 10/880,492

(22) Filed: Jul. 1, 2004

(30) Foreign Application Priority Data
Sep. 26, 2003 (TW) 092126734

(51) Int. Cl. H03K 3/037

(52) U.S. Cl. 327/199

(57) ABSTRACT

A timing-flexible flip-flop element with at least one extra delayed output signal. The timing-flexible flip-flop element includes a flip-flop logic circuit for generating a standard output signal and a delay cell for receiving the standard output signal to generate a delayed output signal. Because the timing-flexible flip-flop element of the invention has at least one extra delayed output signal, the delayed output signal for the flip-flop may be selected for the path that needs longer hold time. Therefore, it is unnecessary to insert any delay cell to the path with insufficient hold time. The timing-flexible flip-flop element can be implemented in the cell-based synthesis design flow.

### BACKGROUND OF THE INVENTION

1. Field of the Invention

The invention relates to a flip-flop, and more particularly to a flip-flop element having output signals with different delayed timings.

2. Description of the Related Art

As the manufacturing technology progressing, the current single chip may accommodate several millions of logic gates. With the need for the chip's operation speed becomes higher and higher, it is an important subject to design a sync circuit on a complex chip. Because a global clock is utilized to control the synchronization of the circuit in the conventional sync circuit, the operation speed is restricted by the longest path in the combinational circuit, and the problem of clock skew will be caused.

In terms of implementing the sync circuit design using the submicron technology, because the case of ASIC (application specific integrated circuit) having the system clock frequency greater than 200 MHz is quite little, the restrictions and problems in the setup time are fewer. However, because the skew for the global clock cannot be reduced simultaneously, the restriction of hold time may become a bottleneck in the design phase. In order to overcome the above-mentioned problems and to achieve the object of system synchronism, an extra delay cell is properly inserted to some paths in order to keep the hold time. However, the delay cell does not have many effects, and there may not be much contribution to overcome clock skew problem by inserting the delay cell or a buffer. In addition, the ASICs that are getting more and more complex utilizes a lot of flip-flops, and the clock tree balancing becomes quite difficult, thereby increasing the system complexity.

Furthermore, as for the metal oxide semiconductor (MOS), because the delay cell needs a longer channel length or a higher input impedance in the manufacturing processes, it is preferred to avoid the usage of the delay cell for keeping the hold time. In addition, because the resistance and the capacitance for the routing in the submicron technology are increased, the clock skew is hard to be reduced and controlled. On the other hand, the excess delay elements may increase the power consumption, and the excess, simultaneous switching power may cause the problem of serious power bouncing in the phase of designing the mixed mode ASICs,

FIG. 1 shows a schematic illustration of a conventional sync design circuit. The circuit is created by a smart synthesis CAD tool. Referring to FIG. 1, the circuit includes three flip-flops 102, 104 and 106, three combinational logic 108, 110 and 112, and two delay cells 114 and 116. In the circuit, the paths 118 and 122 are the critical paths for the hold time, and the path 120 is the critical path for the setup time. In order to implement the system synchronism and to tolerant clock skew effect, the circuit designer has to insert the delay cells 114 and 116 to the paths 118 and 122 respectively, so as to overcome the restriction of the hold time. However, inserting these delay cells may increase the load of the flip-flop 102. Hence, setup time restrictions of the paths 118 and 122 may become greater. Consequently, it is difficult for the smart synthesis CAD tool to optimize the setup time and the hold time of the circuit.

Therefore, as for the system with the sync design, the drawback of the prior art is that all the flip-flops and logic states are switched simultaneously, thereby generating a lot of simultaneous switching powers. Furthermore, the problem of serious power bouncing may interfere with the operations of the mixed mode circuit. On the other hand, as for the system with the non-sync design, the simultaneous switching powers may be reduced. However, the circuit designers have to be retrained to make themselves well know the non-sync design method. Consequently, the design phase and R&D cost may be greatly increased. In addition, most of the synthesis CAD tools do not support the non-sync design.

### SUMMARY OF THE INVENTION

Therefore, one of the objects of the invention is to provide a timing-flexible flip-flop element. In order to optimize the timings, the timing-flexible flip-flop element separates the switch time for the flip-flop. That is, except for the standard output signal of the standard timing, a delayed output signal is further provided. Properly utilizing the output signals with different timings may optimize the sync design and reduce the poor influence caused by switching the power without adding any delay cell to the system.

To achieve the above-mentioned object, the invention provides a timing-flexible flip-flop element including a flip-flop logic circuit for generating a standard output signal, and a delay cell for receiving the standard output signal and generating a delayed output signal.

As mentioned in the preferred embodiments of the invention, the delay cell includes a delay resistor and a delay capacitor. The delay resistor is coupled to the flip-flop logic circuit while the delay capacitor is coupled to the delay resistor.

As mentioned in the preferred embodiments of the invention, the delay cell includes a plurality of phase inverters, and the number of the phase inverters is an even number.

As mentioned in the preferred embodiments of the invention, the delay cell is a MOS (Metal Oxide Semiconductor) phase inverter, which has a substantially longer channel length or a substantially narrower channel length.

As mentioned in the preferred embodiments of the invention, the flip-flop may be applied to an element database required by a CAD software tool.

In summary, the invention provides a timing-flexible flip-flop element. Because the flip-flop provides two output signals with different timings, the sync design with optimum timing design may be achieved without inserting any delay cells. Furthermore, the flip-flop element may be applied to all internal signals of the system and the conventional synthesis CAD tool. In addition, because the complexity of circuit layout and routing when the flip-flop element is applied is not increased, it is possible to greatly reduce the design and manufacturing costs.

### BRIEF DESCRIPTION OF THE DRAWINGS

FIG. 1 shows a schematic illustration of a conventional sync design circuit.

FIG. 2 shows a schematic illustration of a circuit of a timing-flexible flip-flop element according to a first preferred embodiment of the invention.

FIG. 3 shows a circuit of an output delay cell according to the first preferred embodiment of the invention.

FIG. 4 shows another circuit of an output delay cell according to the first preferred embodiment of the invention.

FIG. 5 shows another circuit of an output delay cell according to the first preferred embodiment of the invention.

FIG. 6 shows a sync design circuit according to the first preferred embodiment of the invention.

FIG. 7 shows a circuit of a timing-flexible flip-flop element according to a second preferred embodiment of the invention.

### DETAILED DESCRIPTION OF THE INVENTION

The timing-flexible flip-flop element of the invention will be described with reference to the accompanying drawings.

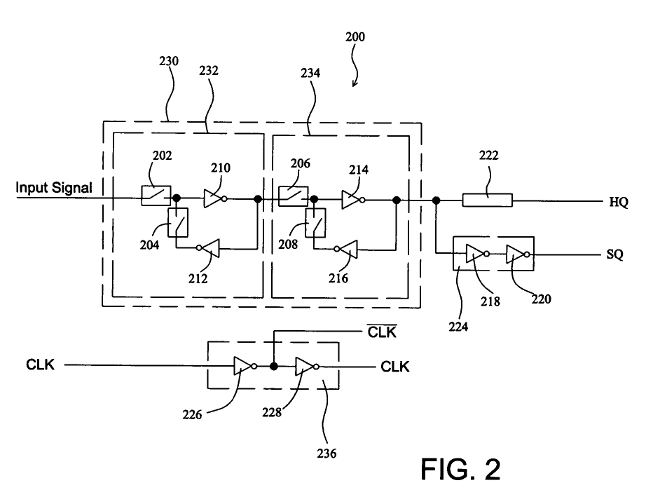

FIG. 2 shows a schematic illustration of a circuit of a timing-flexible flip-flop element according to a first preferred embodiment of the invention. The timing-flexible flip-flop element 200 includes a flip-flop logic circuit 230, a delay cell 222, a buffer interface 224, and a clock circuit 236. The delay cell 222 receives an output of the flip-flop logic circuit 230 and generates a delayed output signal HQ. The buffer interface 224 also receives the output of the flip-flop logic circuit 230 and outputs a standard output signal SQ. The clock circuit 236 receives a clock signal and generates a forward clock and a reverse clock that are required by the flip-flop logic circuit 230.

In general, the flip-flop logic circuit 230 includes a main latch unit 232 and a sub-latch unit 234. The sub-latch unit 234 is coupled to the main latch unit 232. Furthermore, the main latch unit 232 includes a first switch 202, a second switch 204, a first logic gate 210 and a second logic gate 212. The second switch 204 is coupled to the first switch 202, the first logic gate 210 is coupled to the first switch 202 and the second switch 204, and the second logic gate 212 is coupled to the first logic gate 210 and the second switch 204. In addition, the sub-latch unit 234 includes a third switch 206, a fourth switch 208, a third logic gate 214 and a fourth logic gate 216. The fourth switch 208 is coupled to the third switch 206, the third logic gate 214 is coupled to the third switch 206 and the fourth switch 208, and the fourth logic gate 216 is coupled to the third logic gate 214 and the fourth switch 208. The buffer interface 224 is composed of a phase inverter 218 and a phase inverter 220 that are connected in series. The clock circuit 236 includes a phase inverter 226 and a phase inverter 228. The phase inverter 226 has an output terminal to control the first switch 202 and the fourth switch 208, and the phase inverter 228 has an output terminal to control the second switch 204 and the third switch 206.

In this embodiment, each logic gate is the MOS phase inverter. The input signal is inputted from the first switch 202, and the clock signal is inputted to the phase inverter 226. When the logic state of the clock signal is 0, the first switch 202 and the fourth switch 208 are turned on, and the second switch 204 and the third switch 206 are turned off. So, the input signal then is latched into the main latch unit 232. When the logic state of the clock signal is 1, the first switch 202 and the fourth switch 208 is turned off, the second switch 204 and the third switch 206 are turned on, and the main latch unit 232 outputs a second signal to the sub-latch unit 234. Next, the second signal is latched into the sub-latch unit 234. In addition, the sub-latch unit 234 outputs an output signal to the delay cell 222 and the buffer interface 224. Then, the delay cell 222 delays the output signal by a period of first delay time and outputs a delayed output signal HQ. In addition, the buffer interface 224 outputs the output signal as the standard output signal SQ. Because the first delay time is longer than the delay time of the buffer interface 224, the delayed output signal HQ lags behind the standard output signal SQ. Consequently, in order to make the first delay time longer than the delay time of the buffer interface 224, the buffer interface 224 is only composed of the phase inverter 218 and the phase inverter 220 that are connected in series, and the delay cell 222 has to delay the signal by a longer period of time.

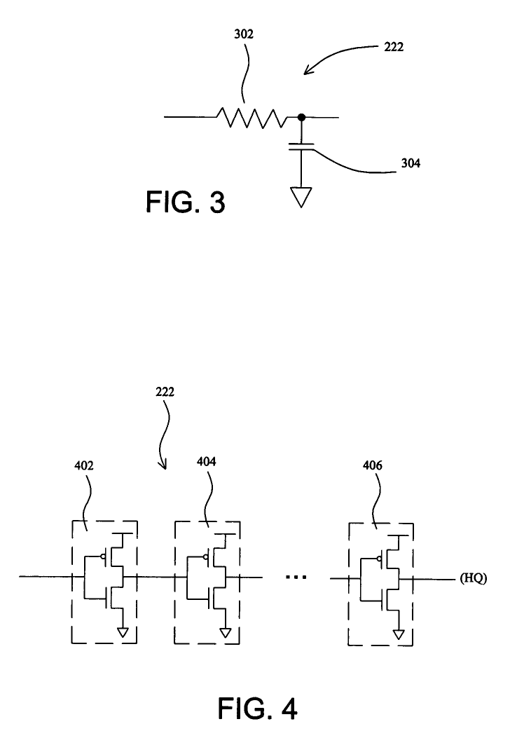

FIG. 3 shows a schematic illustration of a circuit of an output delay cell according to the first preferred embodiment of the invention. As shown in FIG. 3, the delay cell 222 of FIG. 2 may be composed of a resistor 302 and a capacitor 304 which constitute a RC charge/discharge network. The proper delay time may be obtained by adjusting the resistance and capacitance of the resistor 302 and the capacitor 304, respectively.

FIG. 4 shows another circuit of an output delay cell according to the first preferred embodiment of the invention. As shown in FIG. 4, the delay cell 222 of FIG. 2 may be composed of a plurality of phase inverters 402, 404, . . . , 406, in order to obtain a required period of delay time. Thus, the desired delay time may be generated as long as the numbers of inverters are designed to be different. However, in order to keep the logic state unchanged, the total number of the phase inverters has to be an even number.

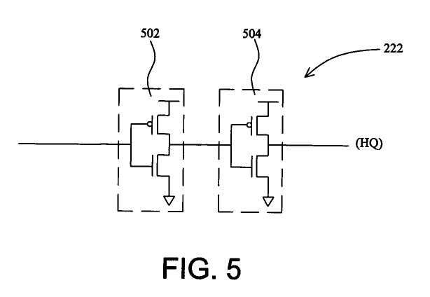

FIG. 5 shows another circuit of an output delay cell according to the first preferred embodiment of the invention. As shown in FIG. 5, the delay cell 222 of FIG. 2 is composed of MOS phase inverters 502 and 504 in this embodiment. Hence, a required period of delay time may be obtained by adjusting the channel lengths or channel widths of the MOS phase inverters 502 and 504.

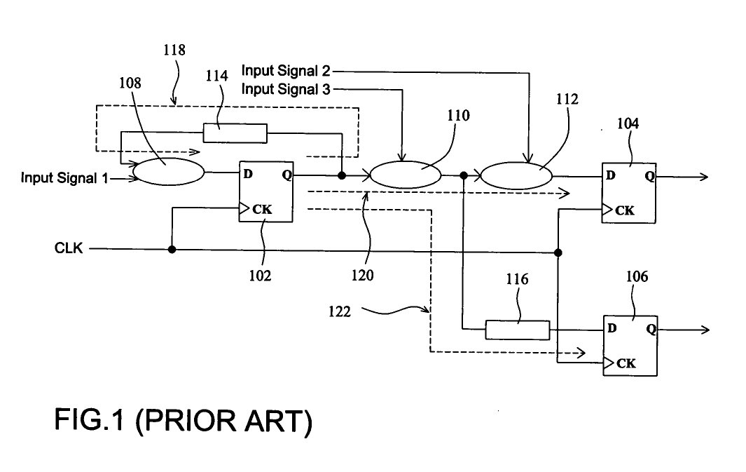

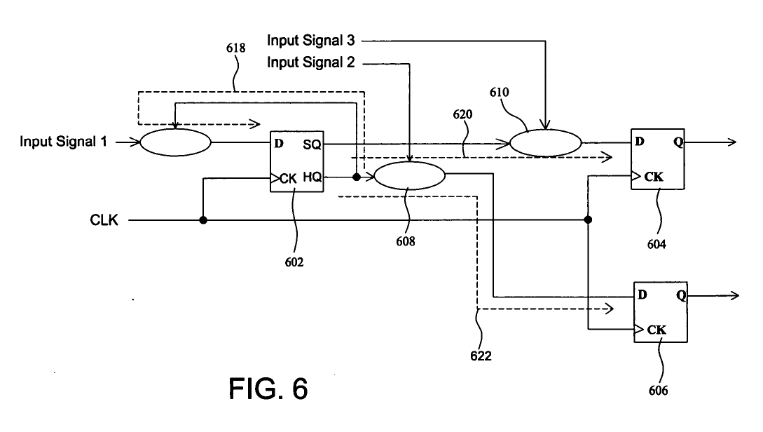

FIG. 6 shows a schematic illustration of a sync design circuit according to the first preferred embodiment of the invention. The sync design circuit utilizes a timing-flexible flip-flop element to improve the drawbacks shown in FIG. 1. Referring to FIGS. 6 and 1, the paths 618 and 622 are the critical paths for the hold time and the path 620 is the critical path for the setup time. In order to satisfy the timing requirements of the hold time of the flip-flops 602 and 606, the paths 618 and 622 are connected to the delayed output terminal HQ of the flip-flop 602. In order to satisfy the timing requirements of the setup time of the flip-flop 604, the path 620 is connected to the standard output terminal SQ of the flip-flop 602. Because the delayed output signal of the timing-flexible flip-flop 602 lags behind the standard output signal, the sync design may be optimized. It is to be noted that the delay cells 114 and 116 in FIG. 1 are omitted after the timing-flexible flip-flop 602 is utilized.

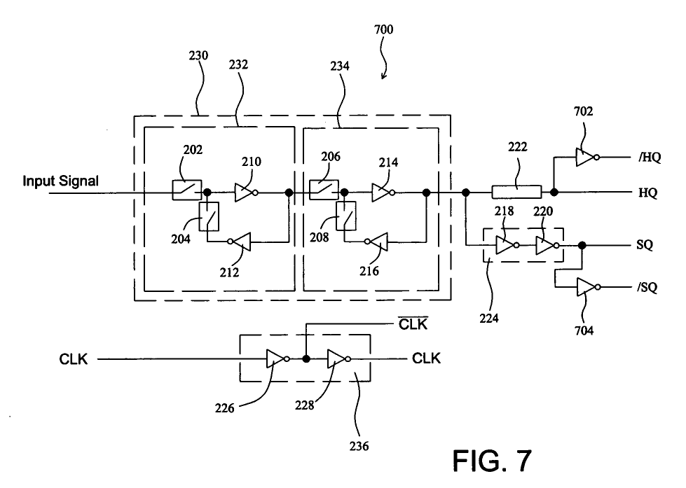

FIG. 7 shows a schematic illustration of a circuit of a timing-flexible flip-flop element according to a second preferred embodiment of the invention. The timing-flexible flip-flop element 700 includes a flip-flop logic circuit 230, a delay cell 222, a buffer interface 224, and a clock circuit 236. The delay cell 222 receives an output of the flip-flop logic circuit 230 and generates a delayed output signal HQ. The buffer interface 224 also receives the output of the flip-flop logic circuit 230 and outputs a standard output signal SQ. The clock circuit 236 receives a clock signal and generates a forward clock and a reverse clock required by the flip-flop logic circuit 230. In addition, the flip-flop element 700 differs from the flip-flop element 200 of FIG. 2 in that two reverse output signals are added. That is, the inverter 702 is utilized to receive the delayed output signal HQ and output a reverse delayed output signal /HQ. In addition, the inverter 704 is utilized to receive the standard output signal SQ and output a reverse standard output signal /SQ.

In summary, the invention provides a timing-flexible flip-flop element. The efficiency of optimizing the timings may be effectively improved if the timing-flexible flip-flop element is utilized and the critical correlation paths of the setup time and the hold time are separated into independent timing paths. Furthermore, the buffer or delay cell does not have to be inserted for the critical path of the hold time. In addition, utilizing the invention may further reduce the routing complexity, the manufacturing cost and the power loss. On the other hand, the synthesis CAD tool may utilize the invention to implement the optimum hold time and setup time of the system.

While certain exemplary embodiments have been described and shown in the accompanying drawings, it is to be understood that such embodiments are merely illustrative of and not restrictive on the broad invention, and that this invention not be limited to the specific construction and arrangement shown and described, since various other modifications may occur to those ordinarily skilled in the art. For instance, the flip-flop logic circuit may further include a clear circuit and a set circuit of the conventional flip-flop logic circuit so as to control the state of the output signal directly. That is, the so-called flip-flop logic circuit of the invention may include the flip-flop logic circuit of the prior art.

1. A timing-flexible flip-flop element, comprising:
a flip-flop logic circuit for receiving at least one input signal and a clock signal, and generating a standard output signal; and
a delay cell for receiving the standard output signal and generating a delayed output signal after delaying the standard output signal by a period of first delay time.

2. The timing-flexible flip-flop element according to claim 1, further comprising a buffer interface, through which the standard output signal is outputted.

3. The timing-flexible flip-flop element according to claim 2, wherein the first delay time is greater than delay time of the buffer interface.

4. The timing-flexible flip-flop element according to claim 1, wherein the delay cell is a resistor-capacitor network.

5. The timing-flexible flip-flop element according to claim 2, wherein the delay cell is a resistor-capacitor network.

6. The timing-flexible flip-flop element according to claim 1, wherein the delay cell comprises a plurality of phase inverters, and the number of the phase inverters is an even number.

7. The timing-flexible flip-flop element according to claim 2, wherein the delay cell comprises a plurality of phase inverters, and the number of the phase inverters is an even number.

8. The timing-flexible flip-flop element according to claim 1, wherein the delay cell comprises two MOS (Metal Oxide Semiconductor) phase inverters in series having a substantially longer channel length or a substantially narrower channel width.

9. The timing-flexible flip-flop element according to claim 2, wherein the delay cell comprises two MOS (Metal Oxide Semiconductor) phase inverters in series having a substantially longer channel length or a substantially narrower channel width.

10. The timing-flexible flip-flop element according to claim 1 being a flip-flop element in an element database required by a synthesis CAD tool.

11. The timing-flexible flip-flop element according to claim 2 being a flip-flop element in an element database required by a synthesis CAD tool.

12. The timing-flexible flip-flop element according to claim 2, wherein the buffer interface is composed of a plurality of phase inverters coupled in series and the number of the phase inverters is an even number.

13. The timing-flexible flip-flop element according to claim 1, wherein the flip-flop logic circuit comprises:
a clock unit for receiving the clock signal and generating a forward clock and a reverse clock;
a main latch unit for receiving the at least one input signal, the forward clock and the reverse clock, and outputting a second signal; and
a sub-latch unit for receiving the second signal, the forward clock and the reverse clock, and generating the standard output signal.

14. The timing-flexible flip-flop element according to claim 2, wherein the flip-flop logic circuit comprises:
a clock unit for receiving the clock signal and generating a forward clock and a reverse clock;
a main latch unit for receiving the at least one input signal, the forward clock and the reverse clock, and outputting a second signal; and
a sub-latch unit for receiving the second signal, the forward clock and the reverse clock, and generating the standard output signal.

15. The timing-flexible flip-flop element according to claim 1, further comprising an inverter for receiving the standard output signal and outputting a reverse standard output signal.

16. The timing-flexible flip-flop element according to claim 2, further comprising an inverter for receiving the standard output signal and outputting a reverse standard output signal.

17. The timing-flexible flip-flop element according to claim 1, further comprising an inverter for receiving the delayed output signal and outputting a reverse delayed output signal.

18. The timing-flexible flip-flop element according to claim 2, further comprising an inverter for receiving the delayed output signal and outputting a reverse delayed output signal.
